(19) United States
(12) Patent Application Publication
(10) Pub. No.: US 2024/0213277 A1
(43) Pub. Date: Jun. 27, 2024

(54) ARRAY SUBSTRATE AND DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventor: Qianyi ZHANG, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 18/149,056

(22) Filed: Dec. 30, 2022

(30) Foreign Application Priority Data
Dec. 22, 2022 (CN) 202211659304.X

(51) Int. Cl. H01L 27/12

(52) U.S. Cl. CPC H01L 27/1255; H01L 27/1248; H01L 27/1259

(57) ABSTRACT

An array substrate and a display panel are provided in the present application. The array substrate includes a thin-film transistor area and a capacitance area located around the thin-film transistor area. The capacitance area includes a substrate, a first insulating layer and a first storage capacitor. The first insulating layer is arranged on the substrate. A plurality of first grooves are defined on the first insulating layer. The first storage capacitor includes a first electrode plate and a second electrode plate arranged opposite and insulated from the first electrode plate. The first electrode plate is arranged on the substrate. The second electrode plate is located at the side of the first insulating layer away from the substrate, and is partially filled in the first grooves.

### FIELD OF INVENTION

The present application relates to a field of display technology, in particular to an array substrate and a display panel.

### DESCRIPTION OF PRIOR ART

Electroluminescent diodes have advantages of simple preparation process, low cost, high luminous efficiency, easy formation of flexible structure, low power consumption, high color saturation and wide viewing angle. a display technology using electroluminescent diodes has become an important display technology.

An organic light emitting diode (OLED) display panel is a current type light emitting device, which mainly includes an anode, a cathode and an organic material functional layer. A main working principle of OLED is that the organic material functional layer is driven by the electric field formed by the anode and cathode, and emits light through carrier injection and recombination. A high resolution OLED display panel is easy to cause insufficient charge and discharge due to process limitations and small capacitance.

### SUMMARY OF INVENTION

An array substrate and a display panel are provided by embodiments of the present application, which are used to solve a problem of insufficient charge and discharge caused by small capacitance of an existing display panel.

An array substrate is provided by an embodiment of the present application, including a thin-film transistor area and a capacitance area located around the thin-film transistor area, wherein the capacitance area includes:

a substrate;

a first insulating layer arranged on the substrate, wherein a plurality of first grooves are defined on the first insulating layer; and

a first storage capacitor, wherein the first storage capacitor includes a first electrode plate and a second electrode plate arranged opposite and insulated from the first electrode plate, the first electrode plate is arranged on the substrate, and the second electrode plate is located at a side of the first insulating layer away from the substrate and is partially filled in the first grooves.

Optionally, in some embodiments provided in the present application, the capacitance area further includes a buffer layer, the buffer layer is arranged on the substrate, and the first electrode plate is located on a side of the buffer layer away from the substrate.

Optionally, in some embodiments provided in the present application, the capacitance area further includes a third electrode plate, the third electrode plate is located between the buffer layer and the substrate, and the third electrode plate and the first electrode plate are configured as a second storage capacitor.

Optionally, in some embodiments provided in the present application, the capacitance area further includes a buffer layer, the buffer layer is arranged on the substrate, and the first electrode plate is located between the buffer layer and the substrate.

Optionally, in some embodiments provided in the present application, the thin-film transistor area includes a thin-film transistor structure, and the thin-film transistor structure includes an active layer, a gate electrode, a source electrode, a drain electrode, and a second insulating layer;

wherein a first contact hole and a second contact hole are defined on the second insulating layer, the source electrode and the drain electrode are arranged on the second insulating layer, and the source electrode and the drain electrode are respectively connected with the active layer through the first contact hole and the second contact hole; and

wherein the first insulating layer is arranged on a same layer as the second insulating layer.

Optionally, in some embodiments provided in the present application, the source electrode, the drain electrode, and the second electrode plate are made of a same material and are located in a same layer.

Optionally, in some embodiments provided in the present application, the active layer and the first electrode plate are made of a same material and are located in a same layer.

Optionally, in some embodiments provided in the present application, the thin-film transistor further includes a passivation layer and a planarization layer, and a plurality of second grooves are defined on the second insulating layer;

wherein the passivation layer is arranged on a side of the second insulating layer away from the substrate, and the passivation layer is filled in the second grooves; and

wherein the planarization layer is arranged on a side of the passivation layer away from the second insulating layer.

Optionally, in some embodiments provided in the present application, the array substrate further includes a wiring area, the wiring area is located around the capacitance area, the wiring area is provided with a first connecting line and a second connecting line, and the first connecting line and the second connecting line are connected through an opening; and

the first connecting line and the third electrode plate are located in a same layer and are made of a same material, and the second connecting line and the second electrode plate are located in a same layer and are made of a same material.

Optionally, in some embodiments provided in the present application, the thin-film transistor area includes a light shielding layer, and the light shielding layer and the third electrode plate are located in a same layer and are made of a same material.

Correspondingly, a display panel is provided by an embodiment of the present application, and includes the above-mentioned array substrate.

An array substrate and a display panel are provided by embodiments of the present application. The array substrate includes the thin-film transistor area and the capacitance area located around the thin-film transistor area. The capacitance area includes the substrate, the first insulating layer and the first storage capacitor. The first insulating layer is arranged on the substrate. The plurality of first grooves are defined on the first insulating layer. The first storage capacitor includes the first electrode plate and the second electrode plate arranged opposite and insulated from the first electrode plate. The first electrode plate is arranged on the substrate. The second electrode plate is located at the side of the first insulating layer away from the substrate, and is partially filled in the first grooves. In the array substrate provided by the embodiment of the present application, by defining the plurality of first grooves on the first insulating layer, the second electrode plate is partially filled in the first grooves, thereby increasing a facing area between the first electrode plate and the second electrode plate, and reducing a distance between the first electrode plate and the second electrode plate, so as to charge storage capacity of the first storage capacitor is increased, and capacitance value is increased, thereby solving the problem of insufficient charge and discharge caused by the small capacitance of the existing array substrate.

### BRIEF DESCRIPTION OF DRAWINGS

In order to more clearly illustrate the embodiments or the technical solutions of the existing art, the drawings illustrating the embodiments, or the existing art will be briefly described below. The drawings in the following description merely illustrate some embodiments of the present application. Other drawings may also be obtained by those skilled in the art according to these figures without paying creative work.

FIG. 1 is a first structural schematic diagram of an array substrate provided by an embodiment of the present application.

FIG. 2 is a second structural schematic diagram of the array substrate provided by an embodiment of the present application.

FIG. 3 is a third structural schematic diagram of the array substrate provided by an embodiment of the present application.

FIG. 4 is a fourth structural schematic diagram of the array substrate provided by an embodiment of the present application.

FIG. 5 is a schematic diagram of a manufacture method for the array substrate provided by an embodiment of the present application.

FIG. 6 is a structural schematic diagram of a display panel provided by an embodiment of the present application.

### DETAILED DESCRIPTION OF PREFERRED EMBODIMENTS

In order to make the objective, technical solution, and advantages of the present application clearer, the present application will be further described in detail below with reference to the accompanying drawings. Referring to the figures in the accompanying drawings. The components with the same reference numbers represent the same or similar components. The following description is based on the illustrated specific embodiments of the present disclosure and should not be construed to limit the other specific embodiments which are not described in detail herein. The word “embodiment” configured in this specification means an example, example, or illustration.

In the description of the present disclosure, it is to be understood that the azimuth or positional relationships indicated by the terms “center”, “longitudinal”, “transverse”, “length”, “width”, “thickness”, “upper”, “lower”, “front”, “back”, “left”, “right”, “vertical”, “horizontal”, “top”, “bottom”, “inside”, “outside”, “clockwise”, “counter-clockwise”, etc., are based on the azimuth or positional relationship shown in the drawings, merely for the purpose of assisting and simplify the description, rather than indicating or implying that the indicated device or element must have a specific orientation, and be constructed and operated in a particular orientation. Therefore, these terms cannot be construed as limiting the present disclosure. In addition, the terms “first” and “second” are only configured for descriptive purposes and cannot be understood as indicating or implying relative importance or implicitly indicating the number of indicated technical features. Therefore, the features defined with “first” and “second” may explicitly or implicitly include one or more of the features. In the description of the present application, “a plurality of” means two or more than two, unless otherwise specifically defined.

An array substrate and a display panel are provided by embodiments of the present application. Each will be described in detail below. It should be noted that the description order of the following embodiments is not intended to limit the preferred order of the embodiments.

An array substrate is provided by an embodiment of the present application. The array substrate includes a thin-film transistor area and a capacitance area located around the thin-film transistor area. The capacitance area includes a substrate, a first insulating layer and a first storage capacitor. The first insulating layer is arranged on the substrate. A plurality of first grooves are defined on the first insulating layer. The first storage capacitor includes a first electrode plate and a second electrode plate arranged opposite and insulated from the first electrode plate. The first electrode plate is arranged on the substrate. The second electrode plate is located at a side of the first insulating layer away from the substrate, and is partially filled in the first grooves.

In the array substrate provided by the embodiment of the present application, by defining the plurality of first grooves on the first insulating layer, the second electrode plate is partially filled in the first grooves, thereby increasing a facing area between the first electrode plate and the second electrode plate, and reducing a distance between the first electrode plate and the second electrode plate, so as to charge storage capacity of the first storage capacitor is increased, and capacitance value is increased, thereby solving a problem of insufficient charge and discharge caused by small capacitance of an existing array substrate.

The array substrate provided by the present application will be described in detail below through specific embodiments.

Please refer to FIG. 1, FIG. 1 is a first structural schematic diagram of the array substrate provided by an embodiment of the present application. The array substrate 10 is provided by the embodiment of the present application. The array substrate 10 includes a capacitance area CA, a thin-film transistor area TA and a wiring area WA. The thin-film transistor area TA is located around the capacitance area. The wiring area WA is located around the thin-film transistor area TA.

The capacitance area includes a substrate 101, a buffer layer 105, a first insulating layer 106a, and a first storage capacitor 103a. The buffer layer 105 is arranged on the substrate 10. The first insulating layer 106a is arranged on the buffer layer 105. A plurality of first grooves Gr1 are defined on the first insulating layer 106a. The first storage capacitor 103a includes a first electrode plate 1031 and a second electrode plate 1032 arranged opposite and insulated from the first electrode plate 1031. The first electrode plate 1031 is arranged between the substrate 101 and the buffer layer 105. The second electrode plate 1032 is located on a side of the first insulating layer 106a away from the substrate 101, and a part of the second electrode plate 1032 is filled in the first grooves Gr1.

In the embodiment of the present application, since a capacitance of the first storage capacitor 103a is directly proportional to facing areas between two electrode plates of the first storage capacitor 103a, and is inversely proportional to distance between the two electrode plates, therefore increasing the facing areas between the two electrode plates of the first storage capacitor 103a and reducing the distance between the two electrode plates can increase capacitance of the capacitor. Since the plurality of first grooves Gr1 are defined on the first insulating layer 106a, the part of the second electrode plate 1032 extends into the first grooves Gr1, thereby increasing the facing area between the first electrode plate 1031 and the second electrode plate 1032, and reducing the distance between the first electrode plate 1031 and the second electrode plate 1032, so that ability of the first storage capacitor 103a to store charges is increased, and the capacitance value is increased, thereby solving the problem of insufficient charge and discharge caused by the small capacitance of the existing array substrate 10.

In the embodiment of the present application, shapes of the first grooves Gr1 may be a semi-transparent square hole such as a square or a rectangle. Depths of the first grooves Gr1 may be between 80 nm and 200 nm. Sizes of the first grooves Gr1 are greater than or equal to 4 microns * 4 microns. A distance between two adjacent first grooves Gr1 is greater than or equal to 4 microns.

The thin-film transistor area TA includes a light shielding layer LS, an active layer 1021, a gate electrode 1022, a source electrode 1023, a drain electrode 1024, a gate insulating layer 107, a second insulating layer 106b, a passivation layer 108, a planarization layer 109 and a first electrode 110. The active layer 1021, the gate electrode 1022, the source electrode 1023, the drain electrode 1024 and the second insulating layer 106b are configured as the thin-film transistor structure 102.

Specifically, the substrate 101 is also located in the thin-film transistor area TA. The light shielding layer LS is arranged on the substrate 101, and the light shielding layer LS is located in a same layer as the first electrode plate 1031. The light shielding layer LS is configured to shield the thin-film transistor structure 102 and prevent external light from irradiating the thin-film transistor structure 102 from a side of the substrate 101. The light-shielding layer LS can shield channel of the thin-film transistor structure 102, so that it is not irradiated by the external light. In this way, it can prevent the channel of the thin-film transistor structure 102 from being irradiated by the external light and cause the thin-film transistor to generate leakage current, thereby preventing the display panel produces defects such as flicker and crosstalk, which affect the display quality of the display panel. In addition, since the first electrode plate 1031 and the light-shielding layer LS can be made through a same photomask, so that a photomask can be saved and manufacturing costs of the array substrate 10 can be reduced.

In some embodiments, materials of the light shielding layer LS include one or any combination of metals such as silver (Ag), magnesium (Mg), aluminum (Al), tungsten (W), copper (Cu), nickel (Ni), chromium (Cr), molybdenum (Mo), titanium (Ti), platinum (Pt), tantalum (Ta), neodymium (Nd) or scandium (Sc), their alloys, their nitrides, etc. a thickness of the light shielding layer LS is greater than or equal to 500 nm.

The buffer layer 105 is also located in the thin-film transistor area TA. The buffer layer 105 covers the light shielding layer LS. Materials of the buffer layer 105 includes but is not limited to silicon containing oxides, nitrides or nitrogen oxides, or the materials of the buffer layer 105 can also include aluminum containing oxides. For example, the material of the buffer layer 105 is at least one of SiOₓ, SiNₓ, SiOₓN_{y} or AlOₓ. The thickness of the buffer layer 105 is greater than or equal to 200 nm.

In some embodiments, the active layer 1021 is arranged on a side of the buffer layer 105 away from the substrate 101. The gate insulation layer 107 is arranged on a side of the active layer 1021 away from the buffer layer 105. The gate electrode 1022 is arranged on a side of the gate insulation layer 107 away from the active layer 1021.

In an embodiment of the present application, materials of the active layer 1021 can be one of indium gallium zinc oxide, indium zinc tin oxide or indium gallium zinc tin oxide or any combination thereof. Materials of the gate electrode 1022, the source electrode 1023 and the drain electrode 1024 include one or any combination of metals such as silver (Ag), magnesium (Mg), aluminum (Al), tungsten (W), copper (Cu), nickel (Ni), chromium (Cr), molybdenum (Mo), titanium (Ti), platinum (Pt), tantalum

(Ta), neodymium (Nd) or scandium (Sc), their alloys, their nitrides, etc. Thicknesses of the source electrode 1023 and the drain electrode 1024 ranges from 200 nm to 1200 nm.

Materials of the gate insulation layer 107 can be one or more combinations of silicon oxide, silicon nitride, high dielectric constant dielectric materials (such as aluminum oxide, hafnium oxide, zirconia, etc.) and organic dielectric materials, and a thickness of the gate insulation layer 107 can be 500 nm to 1000 nm.

The second insulating layer 106b is arranged on a side of the gate electrode 1022 away from the gate insulating layer 107. The first insulating layer 106a and the second insulating layer 106b are arranged on a same layer. It can be understood that the first insulating layer 106a and the second insulating layer 106b are integrally formed structures. A first contact hole Cnt1 and a second contact hole Cnt2 are defined on the second insulating layer 106b. The source electrode 1023 and drain electrode 1024 are arranged on the second insulating layer 106b, and the source electrode 1023 and the drain electrode 1024 are respectively connected with the active layer 1021 through the first contact hole Cnt1 and the second contact hole Cnt2.

In some embodiments, the second electrode plate 1032, the source electrode 1023 and the drain electrode 1024 are located in a same layer and are made of a same material. Since the second electrode plate 1032, the source electrode 1023 and the drain electrode 1024 are located in a same layer and are made of a same material, the second electrode plate 1032, the source electrode 1023 and the drain electrode 1024 can be made of a same photomask, thereby saving a photomask and reducing the manufacturing costs of the array substrate 10.

It should be noted that “same layer” refers to a layer structure formed by a same film forming process to form a specific pattern, and then by a same mask through a one-time composition process. According to different specific figures, a one-time composition process may include multiple exposure, development or etching processes, and specific figures in the formed layer structure may be continuous or discontinuous, and these specific figures may also be at different heights or have different thicknesses.

In some embodiments, a plurality of second grooves Gr2 are defined on the second insulating layer 106b. The second grooves Gr2 are located between the source electrode 1023 and the drain electrode 1024. The passivation layer 108 is arranged on a side of the second insulating layer 106b away from the substrate 101, and the passivation layer 108 is filled in the second grooves Gr2. The planarization layer 109 is arranged on a side of the passivation layer 108 away from the second insulating layer 106b.

In an embodiment of the present application, because the passivation layer 108 is partially filled in the second grooves Gr2, the contact area between the passivation layer 108 and the second insulating layer 106b is increased, and adhesion between the passivation layer 108 and the second insulating layer 106b is improved, thus preventing the source electrode 1023 and the drain electrode 1024 from peeling off from the second insulating layer 106b. Materials of the passivation layer 108 includes at least one of SiOₓ, SiNₓ, SiOₓN_{y} or AlOₓ.

A via hole h2 is defined on the planarization layer 109, and the first electrode 110 is connected with the drain electrode 1024 through the via hole h2.

Materials of the planarization layer 109 are organic polymer materials. In an embodiment of the present application, since the second grooves Gr2 are defined on the second insulating layer 106b, a topography of the array substrate 10 is improved, leveling of flat materials is strengthened, and a gap of the array substrate 10 is reduced.

In the embodiment of the present application, shapes of the second grooves Gr2 may be a semi-transparent square hole such as a square or a rectangle. Depths of the second grooves Gr2 may be between 80 nm and 200 nm. Sizes of the second grooves Gr2 are greater than or equal to 4 microns * 4 microns. A distance between two adjacent second grooves Gr2 is greater than or equal to 4 microns.

In some embodiments, materials of the first insulating layer 106a and the second insulating layer 106b include SiOₓ, SiNₓ, SiOₓN_{y}, AlOₓ or high dielectric constant dielectric materials (such as aluminum oxide, hafnium oxide, zirconium oxide, etc.). Thicknesses of the first insulating layer 106a and the second insulating layer 106b are greater than or equal to 200 nm.

The wiring area WA includes a connecting line 104, and the connecting line 104 includes a first connecting line 1041 and a second connecting line 1042. The substrate 101, the buffer layer 105 and the second insulating layer 106b are also located in the wiring area WA. An opening h1 is defined on the second insulating layer 106b, the first connecting line 1041 and the second connecting line 1042 are connected through the opening h1. the first connecting line 1041 and the first electrode plate 1031 are located in a same layer and are made of a same material, and the second connecting line 1042 and the second electrode plate 1032 are located in a same layer and are made of a same material.

In an embodiment of the present application, the first electrode plate 1031, the light-shielding layer LS, and the first connecting line 1041 are made through a same photomask, the source electrode 1023, the drain electrode 1024, the second connecting line 1042 and the second electrode plate 1032 are made through a same photomask, so that the number of photomasks can be saved and the manufacturing costs of the array substrate 10 can be reduced.

It should be noted that the connecting line 104 may be a power wire or the like in the present application. For example, the connecting line 104 may specifically be a high-voltage power supply wiring or a low-voltage power supply wiring.

It should be noted that the first grooves Gr1, the second grooves Gr2, the first contact hole Cnt1, the second contact hole Cnt2, and the opening h1 are formed through a same mask process in the embodiment of the present application.

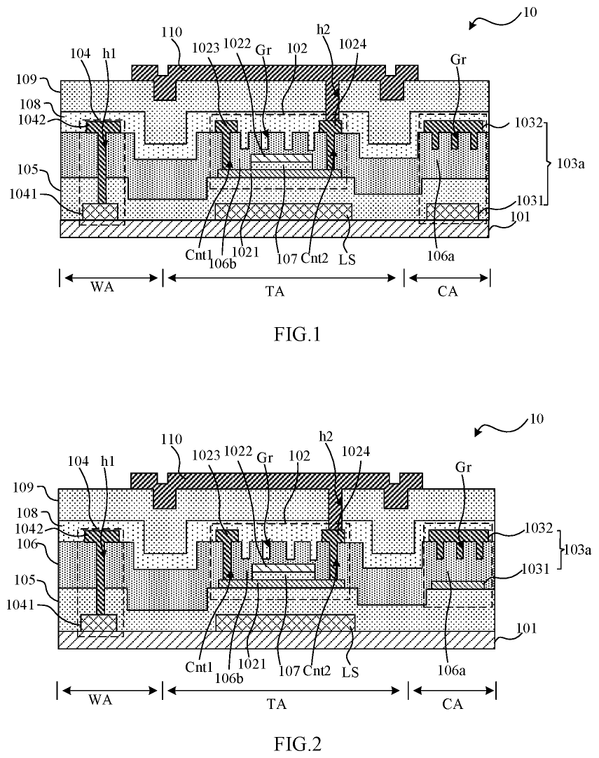

Please refer to FIG. 2, FIG. 2 is a second structural schematic diagram of the array substrate provided by an embodiment of the present application. A difference between the array substrate 10 provided in the embodiment of the present application and the array substrate 10 provided in FIG. 1 is that the first electrode plate 1031 is located on a side of the buffer layer 105 away from the substrate 101. The first electrode plate 1031 and the active layer 1021 are located in a same layer and are made of a same material. In the embodiment of the present application, since the first electrode plate 1031 and the active layer 1021 are located in the same layer and are made of the same material, the first electrode plate 1031 and the active layer 1021 are made through a same photomask, thereby saving the number of photomasks and reducing the manufacturing cost of the array substrate 10.

It should be understood that the first electrode plate 1031 may be formed during a process of conducting the active layer 1021 in the embodiment of the present application.

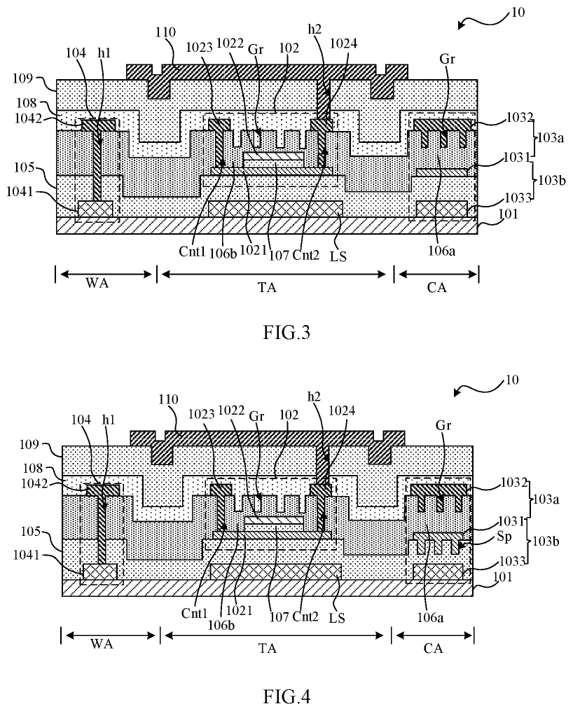

Please refer to FIG. 3, FIG. 3 is a third structural schematic diagram of the array substrate provided by an embodiment of the present application. A difference between the array substrate 10 provided in the embodiment of the present application and the array substrate 10 provided in FIG. 2 is that the capacitance area TA further includes a third electrode plate 1033. The third electrode plate 1033 and the first electrode plate 1031 are configured as a second storage capacitor 103b. The third electrode plate 1033 is located between the buffer layer 105 and the substrate 101. The third electrode plate 1033 and the light-shielding layer LS are located in a same layer and are made of a same material, therefore, the third electrode plate 1033 and the light-shielding layer LS are located in the same layer and are made of the same material, thereby saving the number of photomasks and reducing the manufacturing cost of the array substrate 10.

In an embodiment of the present application, the first electrode plate 1031 and the second electrode plate 1032 are configured as the first storage capacitor 103a, the first electrode plate 1031 and the third electrode plate 1033 are configured as the first storage capacitor 103b, and the first storage capacitor 103a and the second storage capacitor 103b share the first electrode plate 1031, so that the first storage capacitor 103a and the second storage capacitor 103b are configured as a sandwich structure, which increases capacity of the capacitor to store charges.

Capacitance C of a capacitor is relevant to a distance d between the two electrode plates of the capacitor, a dielectric constant ε and a facing area S of the two electrode plates of the capacitor, that is: C=εS/4πkd, k is an electrostatic force constant. It can be seen that the capacitance of the capacitor is inversely proportional to the distance d between the two plates of the capacitor, and the capacitance of the capacitor is directly proportional to the area S of the two plates facing each other. In the embodiment of the present application, the capacitor is designed as a sandwich structure, so that total capacitance is a sum of the first storage capacitor 103a and the second storage capacitor 103b, that is, the total capacitance C is Ctotal=Ca+Cb, Ca is the capacitance of the first storage capacitor 103a, and Cb is the capacitance of the second storage capacitor 103b. In this way, under a condition that the distance d between the two electrode plates of the capacitor remains unchanged, only the first storage capacitor 103a and the second storage capacitor 103b with the two electrode plates having a relatively large facing area can obtain the capacitance of the capacitor, therefore, an area occupied by the array substrate 10 can be further reduced.

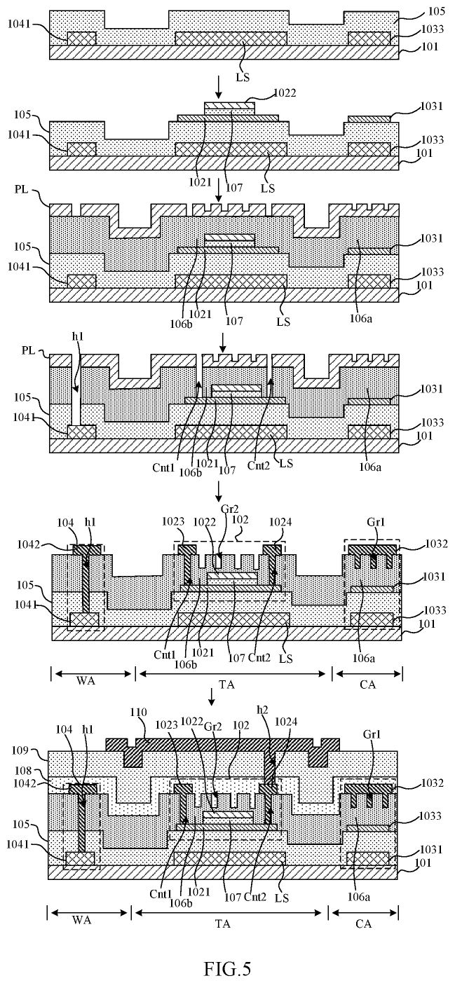

Please refer to FIG. 4, FIG. 4 is a fourth structural schematic diagram of the array substrate provided by an embodiment of the present application. A difference between the array substrate 10 provided in the embodiment of the present application and the array substrate 10 provided in FIG. 3 is that a plurality of depressions Sp are defined on a side of the buffer layer 105 away from the substrate 101, a part of the first electrode plate 1031 is filled in the depressions Sp. In the embodiment of the present application, since the first electrode plate 1031 partially extends into the depressions Sp, a facing area between two electrode plates of the second capacitor 103b increases and a distance decreases, the ability of the capacitor to store charges is further increased, so that the capacitance of the capacitor increases, thereby solving the problem of insufficient charge and discharge caused by the small capacitance of the existing array substrate 10.

Correspondingly, please refer to FIG. 5, FIG. 5 is a schematic diagram of a manufacturing method for an array substrate provided by an embodiment of the present application. The embodiment of the present application also provides the manufacturing method for the array substrate, and the manufacturing method for the array substrate includes the following steps.

Step B001: providing a substrate 101, forming a first metal layer on the substrate 101, and patterning the first metal layer to form a first connecting line 1041, a light shielding layer LS and a third electrode plate 1033. Subsequently, forming a buffer layer 105 on the substrate 101. The buffer layer 105 covers the first connecting line 1041, the light shielding layer LS and the third plate 1033.

Step B002: forming a metal oxide layer in the buffer layer 105, patterning the metal oxide layer, and conducting a part of patterned metal oxide layer to form a doped region and a channel region of the active layer 1021, and the first electrode plate 1031. Next, forming the second insulating layer 106b and the gate electrode 1022 on the active layer 1021. Specifically, an entire layer of the gate insulating layer 107 and the second metal layer can be formed on the substrate 101 first. Patterning the second metal layer to form the gate electrode 1022. Then, the gate insulating layer 107 is patterned by using the gate electrode 1022 as a mask.

Step B003: forming a first insulating layer 106a, a second insulating layer 106b and a photoresist layer PL on the substrate 101, exposing and developing the photoresist layer PL, and then the first insulating layer 106a and the second insulating layer 106b is etched to form an opening h1, a first contact hole Cnt1 and a second contact hole Cnt2. Then, perform ashing treatment on the photoresist layer PL corresponding to first grooves Gr1 and second grooves Gr2, and then etch the first insulating layer 106a and the second insulating layer 106b to form the first grooves Gr1 and the second grooves Gr2, and strip the photoresist layer PL.

Step B004: forming a third metal layer on the first insulating layer 106a and the second insulating layer 106b, and patterning the third metal layer to form a second connecting line 1042, a source electrode 1023, a drain electrode 1024 and a second electrode plate 1032. It should be noted that in this step, the second grooves Gr2 located between the first contact hole Cnt1 and the second contact hole Cnt2 will also be etched.

Step B005: forming a passivation layer 108, a planarization layer 109 and a first electrode 110 on the first insulating layer 106a and the second insulating layer 106b. The first electrode 110 is connected to the drain electrode 1024 through the via hole h2, thereby forming the array substrate 10.

The array substrate 10 is divided into a thin-film transistor area TA, a capacitor area CA and a wiring area WA. The thin-film transistor structure 102 is located in the thin-film transistor area TA, and the active layer 1021, the gate electrode 1022, the source electrode 1023 and the drain electrode 1024 form a thin-film Transistor structure 102. The capacitance area CA includes a first electrode plate 1031, a second electrode plate 1032 and a third electrode plate 1033. The first electrode plate 1031 and the second electrode plate 1032 are configured as the first storage capacitor 103a. The first electrode plate 1031 and the third electrode plate 103b are configured as the second storage capacitor 103b. The connecting lines 104 include a first connecting line 1041 and a second connecting line 1042 connected through the opening h1.

In the manufacturing method of the array substrate provided by an embodiment of the present application, the opening h1, the first contact hole Cnt1, the second contact hole Cnt2, the first grooves Gr1 and the second grooves Gr2 are formed by a half-tone masking process. Since the plurality of first grooves Gr1 are defined on the first insulating layer 106a, and the part of the second electrode plate 1032 extends into the first grooves Gr1, thereby increasing the facing area between the first electrode plate 1031 and the second electrode plate 1032, and reducing the distance between the first plate 1031 and the second plate 1032, so that the ability of the first storage capacitor 103a to store charges is increased, and the capacitance value is increased, thereby solving the problem of insufficient charge and discharge caused by the small capacitance of the existing array substrate 10. At a same time, the topography of the array substrate 10 is improved, the leveling of flat materials is enhanced, and the gap of the array substrate 10 is reduced.

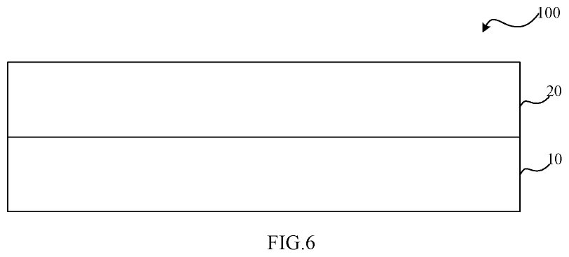

Please refer to FIG. 6, FIG. 6 is a structural schematic diagram of a display panel provided by an embodiment of the present application. The display panel 100 provided by the embodiment of the present application includes an array substrate 10 and a light-emitting functional layer 20 arranged on the array substrate 10.

The array substrate 10 may be the array substrate 10 provided in any of the above-mentioned embodiments, and the light-emitting functional layer 20 may include a pixel definition layer, a light-emitting layer and a second electrode.

The light emitting layer is defined in an opening of the pixel definition layer, and the second electrode is arranged on the light emitting layer.

It should be understood that when the array substrate 10 is provided with the light-emitting functional layer 20, the display panel is an active light-emitting display panel, such as an organic light-emitting diode display panel, an active matrix organic light-emitting diode display panel, a passive matrix organic light-emitting diode display panel, a quantum dot organic light-emitting diode display panel, a micro light-emitting diode display panel and a sub-millimeter light-emitting diode display panels, etc.

In another embodiment, the display panel includes an array substrate 10, a color filter substrate arranged opposite to the array substrate 10, and a liquid crystal layer arranged between the array substrate 10 and the color filter substrate. At this time, the display panel is a passive light-emitting display panel.

In summary, although the present application has been disclosed in preferred embodiments as above, the above-mentioned preferred embodiments are not intended to limit the present application. Those of ordinary skill in the art can make various modifications without departing from the spirit and scope of the present application. Therefore, the protection scope of the present application is subject to the scope defined by the claims.

What is claimed is:

1. An array substrate, comprising a thin-film transistor area and a capacitance area located around the thin-film transistor area, wherein the capacitance area comprises:
a substrate;
a first insulating layer arranged on the substrate, wherein a plurality of first grooves are defined on the first insulating layer; and
a first storage capacitor, wherein the first storage capacitor comprises a first electrode plate and a second electrode plate arranged opposite and insulated from the first electrode plate, the first electrode plate is arranged on the substrate, and the second electrode plate is located at a side of the first insulating layer away from the substrate and is partially filled in the first grooves.

2. The array substrate according to claim 1, wherein the capacitance area further comprises a buffer layer, the buffer layer is arranged on the substrate, and the first electrode plate is located on a side of the buffer layer away from the substrate.

3. The array substrate according to claim 2, wherein the capacitance area further comprises a third electrode plate, the third electrode plate is located between the buffer layer and the substrate, and the third electrode plate and the first electrode plate are configured as a second storage capacitor.

4. The array substrate according to claim 1, wherein the capacitance area further comprises a buffer layer, the buffer layer is arranged on the substrate, and the first electrode plate is located between the buffer layer and the substrate.

5. The array substrate according to claim 1, wherein the thin-film transistor area comprises a thin-film transistor structure, and the thin-film transistor structure comprises an active layer, a gate electrode, a source electrode, a drain electrode, and a second insulating layer;
wherein a first contact hole and a second contact hole are defined on the second insulating layer, the source electrode and the drain electrode are arranged on the second insulating layer, and the source electrode and the drain electrode are respectively connected with the active layer through the first contact hole and the second contact hole; and
wherein the first insulating layer is arranged on a same layer as the second insulating layer.

6. The array substrate according to claim 5, wherein the source electrode, the drain electrode, and the second electrode plate are made of a same material and are located in a same layer.

7. The array substrate according to claim 5, wherein the active layer and the first electrode plate are made of a same material and are located in a same layer.

8. The array substrate according to claim 5, wherein the thin-film transistor further comprises a passivation layer and a planarization layer, and a plurality of second grooves are defined on the second insulating layer;
wherein the passivation layer is arranged on a side of the second insulating layer away from the substrate, and the passivation layer is filled in the second grooves; and
wherein the planarization layer is arranged on a side of the passivation layer away from the second insulating layer.

9. The array substrate according to claim 5, wherein the array substrate further comprises a wiring area, the wiring area is located around the capacitance area, the wiring area is provided with a first connecting line and a second connecting line, and the first connecting line and the second connecting line are connected through an opening; and
the first connecting line and the third electrode plate are located in a same layer and are made of a same material, and the second connecting line and the second electrode plate are located in a same layer and are made of a same material.

10. The array substrate according to claim 3, wherein the thin-film transistor area comprises a light shielding layer, and the light shielding layer and the third electrode plate are located in a same layer and are made of a same material.

11. A display panel, wherein the display panel comprises an array substrate, the array substrate comprises a thin-film transistor area and a capacitance area located around the thin-film transistor area, and the capacitance area comprises:
a substrate;
a first insulating layer arranged on the substrate, wherein a plurality of first grooves are defined on the first insulating layer; and
a first storage capacitor, wherein the first storage capacitor comprises a first electrode plate and a second electrode plate arranged opposite and insulated from the first electrode plate, the first electrode plate is arranged on the substrate, and the second electrode plate is located at a side of the first insulating layer away from the substrate, and is partially filled in the first grooves.

12. The display panel according to claim 11, wherein the capacitance area further comprises a buffer layer, the buffer layer is arranged on the substrate, and the first electrode plate is located on a side of the buffer layer away from the substrate.

13. The display panel according to claim 12, wherein the capacitance area further comprises a third electrode plate, the third electrode plate is located between the buffer layer and the substrate, and the third electrode plate and the first electrode plate are configured as a second storage capacitor.

14. The display panel according to claim 11, wherein the capacitance area further comprises a buffer layer, the buffer layer is arranged on the substrate, and the first electrode plate is located between the buffer layer and the substrate.

15. The display panel according to claim 11, wherein the thin-film transistor area comprises a thin-film transistor structure, and the thin-film transistor structure comprises an active layer, a gate electrode, a source electrode, a drain electrode and a second insulating layer;
wherein a first contact hole and a second contact hole are defined on the second insulating layer, the source electrode and the drain electrode are arranged on the second insulating layer, and the source electrode and the drain electrode are respectively connected with the active layer through the first contact hole and the second contact hole; and
wherein the first insulating layer is arranged on a same layer as the second insulating layer.

16. The display panel according to claim 15, wherein the source electrode, the drain electrode and the second electrode plate are made of a same material and are located in a same layer.

17. The display panel according to claim 15, wherein the active layer and the first electrode plate are made of a same material and are located in a same layer.

18. The display panel according to claim 15, wherein the thin-film transistor further comprises a passivation layer and a planarization layer, and a plurality of second grooves are defined on the second insulating layer;
wherein the passivation layer is arranged on a side of the second insulating layer away from the substrate, and the passivation layer is filled in the second grooves; and
wherein the planarization layer is arranged on a side of the passivation layer away from the second insulating layer.

19. The display panel according to claim 15, wherein the array substrate further comprises a wiring area, the wiring area is located around the capacitance area, the wiring area is provided with a first connecting line and a second connecting line, and the first connecting line and the second connecting line are connected through an opening; and
the first connecting line and the third electrode plate are located in a same layer and are made of a same material, and the second connecting line and the second electrode plate are located in a same layer and are made of a same material.

20. The display panel according to claim 13, wherein the thin-film transistor area comprises a light shielding layer, and the light shielding layer and the third electrode plate are located in a same layer and are made of a same material.
